(19) United States
(12) Patent Application Publication
(10) Pub. No.: US 2026/0363025 A1
(43) Pub. Date: Nov. 12, 2026

(54) DIE BONDING SYSTEM

(71) Applicant: Taiwan Semiconductor Manufacturing Company, Ltd., Hsinchu (TW)

(72) Inventors: Yi-Chu WU, Hsinchu (TW); Jen-Yuan Chang, Hsinchu (TW)

(73) Assignee: Taiwan Semiconductor Manufacturing Company, Ltd., Hsinchu (TW)

(21) Appl. No.: 19/747,364

(22) Filed: Jul. 20, 2026

Related U.S. Application Data
(62) Division of application No. 18/195,725, filed on May 10, 2023.

(51) Int. Cl. H10P 72/78; B25B 11/00; H05K 13/04; B23K 1/00; B23K 37/04; B23K 101/40

(52) U.S. Cl. CPC H10P 72/78; B25B 11/005; H05K 13/0409; B23K 1/0016; B23K 37/0408; B23K 2101/40; Y10T 29/49133

(57) ABSTRACT

A die bonding system includes a pick-and-placer, a carrier fixing platform and a transfer platform. The pick-and-placer includes a suction head for picking up a die and placing the die on a carrier. The carrier fixing platform is for fixing the carrier, and the carrier has a bearing surface tilting an angle relative to a horizontal plane. The transfer platform is for controlling the pick-and-placer to bond the die to the bearing surface of the carrier at the angle of tilt.

This application is a divisional application of US application number 18/195,725, filed May 10, 2023, the disclosure of which is incorporated by reference herein in its entirety.

### BACKGROUND

The system-on-integrated chip (SoIC) packaging technology adopted by the chip package manufacture is based on wafer-on-wafer (WoW) and chip-on-wafer (CoW) multi-chip stacking technologies, in which the dies are stacked in a face-to-face or face-to-back manner to connect to each other.

For SoIC pick-and-place bonding process, top die control during bonding is the most important key factor of yield evaluation. Bonding condition of the pick-and-place bonder can also affect the quality of plane-to-plane bonding. Once the particles fall on the wafer or the dies, the bonding interface can be distorted and then affect the reliability of bonding interface between the wafer and the die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A and FIG. 1B are schematic diagrams of a die bonding system and a die bonding method using the same according to an embodiment of the present disclosure.

FIGS. 2A and 2B are schematic diagrams of a die bonding system and a die bonding method using the same according to another embodiment of the present disclosure.

FIGS. 3A and 3B are schematic diagrams of a die bonding system and a die bonding method using the same according to another embodiment of the present disclosure.

FIGS. 3C and 3D are schematic diagrams of a die bonding system and a die bonding method using the same according to another embodiment of the present disclosure.

FIGS. 4A and 4B are schematic diagrams of a die bonding system and a die bonding method using the same according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

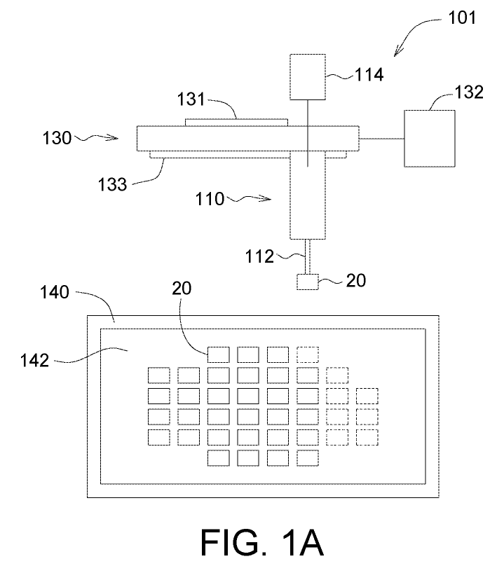

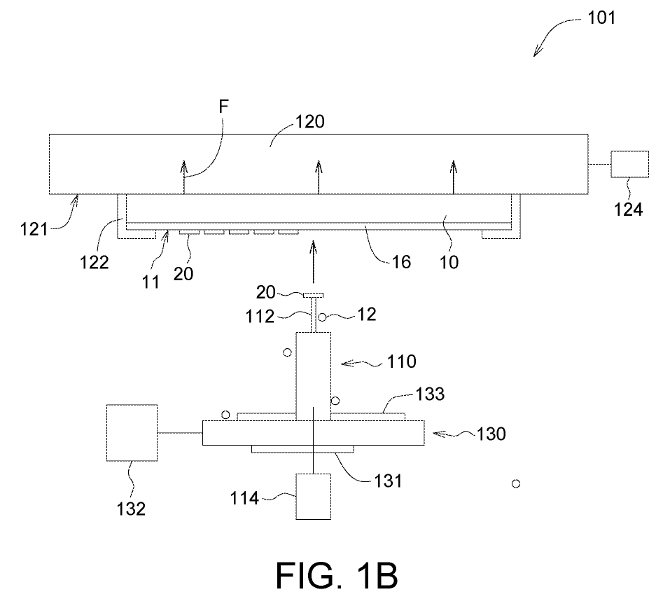

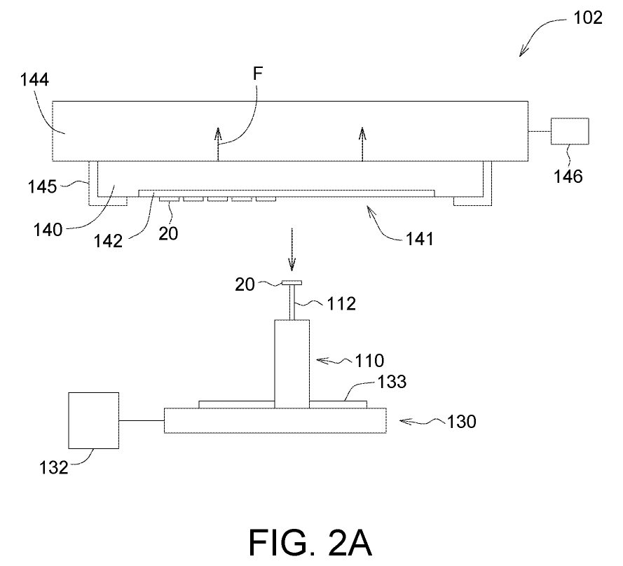

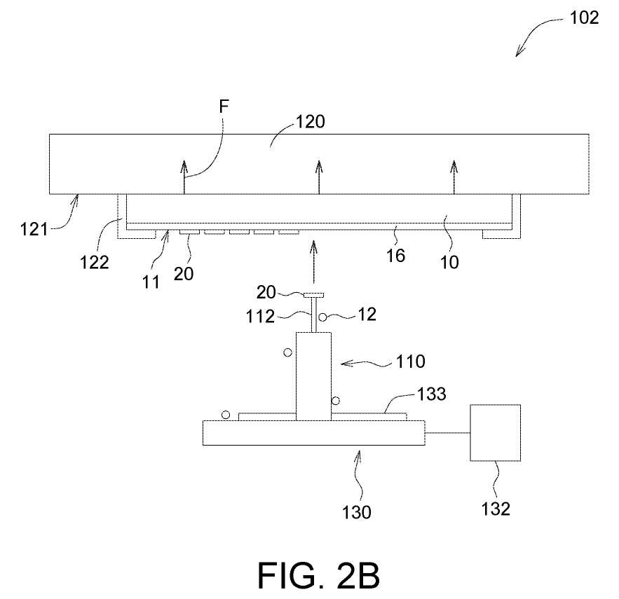

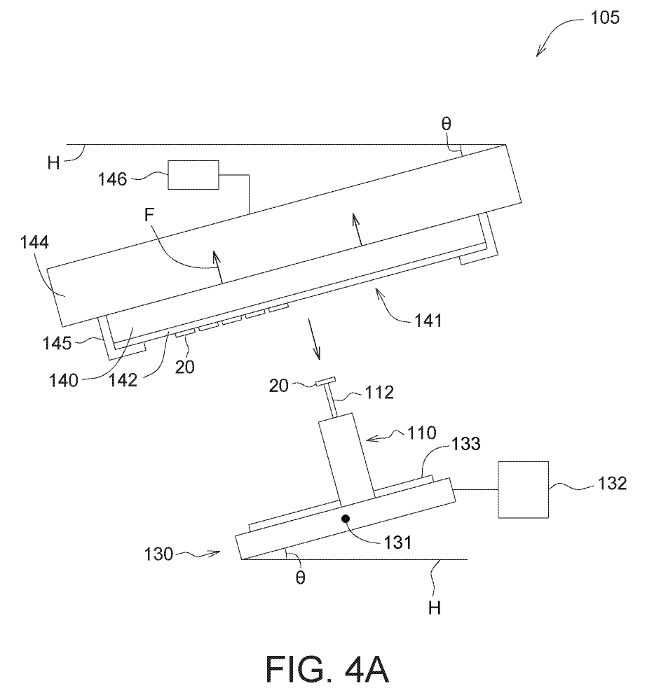

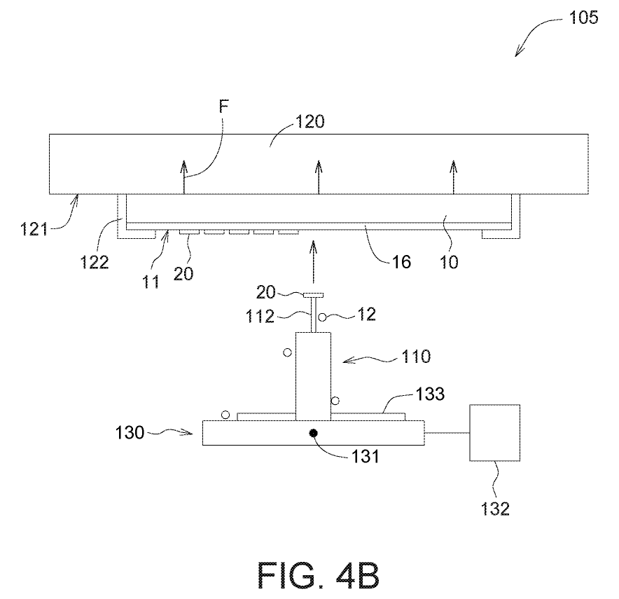

According to some embodiments of the present disclosure, in order to avoid the contaminants falling on the carrier or the dies and to prevent the occurrence of a non-bonding interface between the carrier and the dies, the carrier and the carrier fixing platform are arranged to face downward as shown in FIGS. 1B, 2B and 4B and/or the dies and the die frame are arranged to face downward as shown in FIGS. 2A and 4A.

Referring to FIGS. 1A and 1B, schematic diagrams of a die bonding system 101 and a die bonding method according to an embodiment of the disclosure are shown. A die bonding system 101 includes a pick-and-placer 110, a die frame 140, a carrier fixing platform 120 and a transfer platform 130. The pick-and-placer 110 is mounted on the transfer platform 130, and the transfer platform 130 can generally be a pick-and-place machine with a two-axis moving stage and a servo controller, such as the Datacon™ 2200 evo multi-chip die bonder offered by BE Semiconductor Industries N.V., Shibaura Mechatronics Co., Ltd., Model: TFC-6000, or other similar machines. The pick-and-placer 110 can complete the pick-and-place operation of the die 20 through the movement of the robotic arm and numerical control. The pick-and-place machine and the robotic arm are used for transferring the pick-and-placer 110 to the carrier 10 (such as a wafer). The pick-and-placer 110 is used to pick up a die 20 on the die frame 140 and place the die 20 on a bearing surface 11 of the carrier 10.

In some embodiments, the carrier 10 (i.e., wafer) may include glass, silicon, germanium, a printed circuit board (PCB) and the like. The thickness of the carrier 10 may be between about a few mils to several tens of mils and the carrier 10 may have a diameter of about 300 mm in some embodiments. The carrier 10 functions as a fan-out carrier wafer during the packaging of semiconductor devices or dies.

In some embodiments, the die 20 may be a central processing unit (CPU) die, a graphics processing unit (GPU) die, a system-on-a-chip (SoC) unit die or a high bandwidth memory (HBM), a power management die (for example, power management integrated circuit (PMIC)), a radio frequency (RF) die, a sensor die, a micro-electro-mechanical-system (MEMS) die, or a signal processing die (such as digital signal processor, DSP). As shown in FIG. 1A, the dies 20 are collected and stored in a die frame 140 (e.g., waffle pack) or on a dicing tape 142, and the die 20 can be picked up by the pick-and-placer 110 from the die frame 140 or the dicing tape 142.

In some embodiments, the die frame 140 (e.g., waffle pack) is a carrier for bare dies 20 used for the transportation and handling of a small batch of dies. The waffle pack is typically a plastic tray with pockets sized up for a particular die size. For example, the die frame 140 is a six by six waffle pack populated with 36 dies, and the present disclosure is not limited thereto.

In some embodiments, before placing the die 20 on the carrier 10, a bonding film 16 can be formed on the carrier 10. The bonding film 16 can be a silicon dioxide film, and its thickness is, for example, between 0.1 micron and 1 micron. The bonding film 16 can generate a weak Van der Waals force between the die 20 and the carrier 10 due to direct room temperature bonding, so that the bonding surface of the die 20 can be completely attached to the bonding film 16.

In some embodiments, a combination of a metal-to-metal bonding and a dielectric-to-dielectric bonding or a fusion bonding is used to bond the die 20 on the carrier 10. The combination of a metal-to-metal bonding and a dielectric-to-dielectric bonding or the fusion bonding includes pre-bonding and annealing. During the pre-bonding, a small pressure is applied to bond the die 20 on the carrier 10 by van der Waals force. Pre-bonding may be performed at room temperature (e.g., between about 21℃ and about 25℃) or higher temperatures.

In some embodiments, the carrier 10 is disposed under the carrier fixing platform 120, the carrier 10 has a bearing surface 11, and the bearing surface 11 is arranged to face downward. The carrier fixing platform 120 can be a wafer stage/table, an electrostatic chuck (e-chuck), or other devices with the same concept. The area of the carrier fixing platform 120 is greater than that of the carrier 10 (e.g., wafer). The diameter of carrier 10 may be in a range of 200mm to 450mm, such as about 200 mm, about 300 mm, about 450 mm, or any suitable size. In some embodiments, the carrier fixing platform 120 is designed to have a plurality of wafer support pins that can move independently (independent to each other) and vertically (perpendicular to the surface of the wafer being supported thereon), but there may be no wafer support pin thereon. In some other embodiments, the electrostatic chuck is designed as a device that uses electricity to generate electrostatic force, such as Coulomb force and Johnsen-Rahbek force, to maintain the position of the carrier 10.

Referring to FIG. 1A and FIG. 1B, the pick-and-placer 110 includes a suction head 112, the suction head 112 is used to pick up a die 20 and place the die 20 on a carrier 10, the carrier fixing platform 120 is used to fix the carrier 10, the carrier 10 has a bearing surface 11 which is arranged to face downward. The transfer platform 130 is connected to a driver 132, the pick-and-placer 110 is arranged on the transfer platform 130, and the driver 132 controls the pick-and-placer 110 to move to a location under the carrier 10, and the pick-and-placer 110 carries the die 20 to be bonded to the bearing surface 11 of the carrier 10 from the location under the carrier 10.

In some embodiments, the suction head 112 can be a vacuum chuck. As shown in FIG. 1A, a vacuum generator (e.g., pump) 114 can be connected to the suction head 112 through a pipeline, so that the pick-and-placer 110 can fix the die 20 during a vacuuming period. After the vacuum generator 114 is turned off to release the vacuum in the suction head 112, the pick-and-placer 110 can release the die 20 during a vacuum release period, so that the die 20 can be bonded to the carrier 10 through the bonding film 16 or a conductive bump (not shown).

In some embodiments, the carrier 10 may be a bulk semiconductor wafer. For example, the carrier 10 may include compound semiconductors. The compound semiconductor may include gallium arsenide, silicon carbide, indium arsenide, indium phosphide, other suitable materials, or combinations thereof. However, in other embodiments, the carrier 10 may include alloy semiconductors, such as silicon germanium, silicon germanium carbide, gallium arsenic phosphide, or gallium indium phosphide ( gallium indium phosphide). In other embodiments, the carrier 10 may include a silicon-on-insulator (SOI) or germanium-on-insulator (GOI) substrate. The SOI substrate can be made by separation by implantation of oxygen technology, wafer bonding technology, other suitable technologies, or a combination of the above.

In some embodiments, interconnection structures may be formed on the carrier 10. The interconnection structure may include a plurality of interlayered dielectric layers, such as a low-k material with a small relative dielectric constant relative to silicon dioxide. Replacing the silicon dioxide with a low-k dielectric of the same thickness reduces parasitic capacitance, enabling faster switching speeds (in case of synchronous circuits) and lower heat dissipation. The interconnection structure may also include multilayer conductive features formed between interlayered dielectric layers, such as conductive lines, conductive vias, and/or various conductive contacts.

In some embodiments, the carrier 10 includes different device elements. For example, device elements may include transistors (such as metal oxide semiconductor field effect transistors (MOSFETs), complementary metal oxide semiconductor (CMOS) transistors, bipolar junction transistor (BJT), high-voltage transistor, high-frequency transistor, p-channel and/or n-channel field-effect transistor (PFET and /or NFET), diodes, or other suitable components). Different device elements may use different process methods, including deposition, etching, implantation, lithography, annealing, and/or other suitable process methods.

In some embodiments, the device elements in the carrier 10 may be connected to each other via interconnection structures to form an integrated circuit device. Integrated circuit devices may include logic devices, memory devices (such as static random access memory (SRAM)), radio frequency (RF) devices, input/output (I/O) device, a system-on-chip (SOC) device, an image sensor device, other suitable devices, or combinations of the above devices.

In FIG. 1B, in order to avoid the contaminants (e.g., particles 12 or undesired objects) from the surface of the carrier fixing platform 120 falling on the carrier 10 or the dies 20 before the die bonding process and to prevent the possibility of the occurrence of a non-bonding interface between the carrier 10 and the dies 20 during the pick-and-place bonding process due to the formation of voids or gaps between the carrier 10 and the dies 20, the carrier fixing platform 120 and the carrier 10 are arranged to face downward. Since the carrier fixing platform 120 and the carrier 10 face downward, the particles 12 originally attached to the carrier fixing platform 120 and the carrier 10 fall down due to gravity. The particles 12 also can be removed by other external forces (such as a jet stream or an electrostatic force). Therefore, the bearing surface 121 of the carrier fixing platform 120 and the bearing surface 11 of the carrier 10 can keep clean without being polluted by particles 12 or other undesired contaminants so as not to produce a defective carrier 10. The particles 12 may come from particles in the gas, pollutants generated during the manufacturing process, particles originally attached to the die or wafer, or other devices that generate particles 12. The particles 12 may contaminate the carrier 10 in the die bonding process to produce a defective carrier 10.

In some embodiments, the carrier fixing platform 120 can use mechanical elements, vacuum adsorption elements, electrostatic adsorption elements, clamping elements or other elements to hold the carrier 10. As shown in FIG. 1B, at least two fixing parts 122 are provided on the bearing surface 121 of the carrier fixing platform 120, such as hooks or chucks, and the two fixing parts 122 can hold the carrier 10 on the bottom of the carrier fixing platform 120. Alternatively, the carrier 10 can be adsorbed on the bottom of the carrier fixing platform 120 by electrostatic force or vacuum suction (the upward arrows on the rear of the carrier 10 shown in FIG. 1B indicates the suction force F). Therefore, the use of mechanical elements or clamping elements to hold the carrier 10 is not limited. That is to say, the carrier fixing platform 120 can be a vacuum holding stage, an electrostatic holding stage or a mechanical holding stage.

In some embodiments, the carrier fixing platform 120 can be driven by a driving device 124 (as shown in FIG. 1B), and the driving device 124 is used to control the movement of the carrier fixing platform 120, including horizontal movement, vertical movement, rotation and/or tilt etc. The driving device may include, for example, a robot arm, a motor, a gear, a linear transmission module or a combination thereof.

In some embodiments, the pick-and-placer 110 is arranged on the transfer platform 130, the transfer platform 130 can be driven by a driver 132, and the driver 132 is used to control the movement of the carrier fixing platform 120, including horizontal movement, vertical movement, rotation and/or tilt, etc. The driver 132 may include, for example, a robot arm, a motor, a gear, a linear transmission module 133 or a combination thereof. The driver 132 is used to control the pick-and-placer 110 to move to a location under the carrier 10, so that the pick-and-placer 110 can bond the die 20 to the bearing surface 11 of the carrier 10 from the location under the carrier 10. In addition, the pick-and-placer 110 can move to the carrier fixing platform 120 through the linear transmission module 133, and the driver 132 is used to control a rotation of the linear transmission module 133 relative to the rotating shaft 131 for rotating the pick-and-placer 110 upward or downward.

As shown in FIGS. 1A and 1B, the driver 132 controls the pick-and-placer 110 to move to the top of the die frame 140, and the suction head 112 of the pick-and-placer 110 moves downward to pick up a die 20, and the die 20 is placed on the dicing tape 142. Next, the driver 132 controls the pick-and-placer 110 to rotate 180 degrees, so that the suction head 112 of the pick-and-placer 110 faces upward, and the die 20 is also set upward. Next, the driver 132 controls the pick-and-placer 110 to move to a location under the carrier fixing platform 120, the die 20 faces the carrier 10 located under the carrier fixing platform 120, and the bearing surface 11 of the carrier 10 is set downward. Then, the suction head 112 of the pick-and-placer 110 moves upward, so that the die 20 is bonded to the bearing surface 11 of the carrier 10.

In some embodiments, when the carrier fixing platform 120 and the carrier 10 are changed to face downward, the particles 12 originally attached to the carrier fixing platform 120 and the carrier 10 fall down due to gravity. Besides, the particles 12 may also be removed by an external force (such as a jet stream or electrostatic force). In addition, the combination of a metal-to-metal bonding and a dielectric-to-dielectric bonding or the fusion bonding is used to bond the die 20 on the carrier 10, and the bonding film 16 can generate a weak Van der Waals force between the die 20 and the carrier 10, so that the die 20 will not drop from the carrier 10. Furthermore, the die 20 can be completely attached to the bonding film 16 without particles falling thereon, reducing the probability of forming voids due to incomplete bonding (non-bonding) between the die 20 and the carrier 10.

Referring to FIG. 2A and FIG. 2B, FIGS. 2A and 2B are schematic diagrams of a die bonding system 102 and a die bonding method using the same according to an embodiment of the present disclosure. The die bonding system 102 includes a pick-and-placer 110, a die frame 140, a carrier fixing platform 120 and a transfer platform 130. The pick-and-placer 110 includes a suction head 112, the suction head 112 is used to pick up a die 20 and place the die 20 on a carrier 10, the carrier fixing platform 120 is used to fix the carrier 10, the carrier 10 has a bearing surface 11 which is arranged to face downward. The transfer platform 130 includes a driver 132, the pick-and-placer 110 is arranged on the transfer platform 130, and the driver 132 controls the pick-and-placer 110 to move to a location under the carrier 10, and the pick-and-placer 110 bonds the die 20 to the bearing surface 11 of the carrier 10 from the location under the carrier 10.

In some embodiments, a plurality of dies 20 and the die frame 140 are arranged below the die frame fixing platform 144, the dies 20 are arranged on the dicing tape 142, the die frame 140 has a bearing surface 141, and the bearing surface 141 faces downward. The die frame fixing platform 144 can be a stage/table, an electrostatic chuck (e-chuck), or other devices with the same concept. The die frame fixing platform 144 has a greater area than the die frame 140. In some embodiments, the die frame fixing platform 144 is arranged to have a plurality of die frame support pins that can be moved independently (independent to each other) and vertically (perpendicular to the surface of the die frame 140 to be supported thereon), but there may be no die frame support pins thereon. In other embodiments, the electrostatic chuck is arranged as a device that uses electricity to generate electrostatic force, such as Coulomb force and Johnsen-Rahbek force, to maintain the position of the die frame 140.

In some embodiments, the die frame fixing platform 144 can use mechanical elements, vacuum adsorption elements, electrostatic adsorption elements, clamping elements or other elements to hold the die frame 140. As shown in FIG. 2B, at least two fixing parts 145, such as hooks or chucks, are disposed on the die frame fixing platform 144, and the two fixing parts 145 hold the die frame 140 on a location under the die frame fixing platform 144. Alternatively, the die frame 140 can be adsorbed under the die frame fixing platform 144 by electrostatic force or vacuum suction (the upward arrow shown in FIG. 2B indicates the suction force F). Therefore, the use of mechanical elements or clamping elements to hold the die frame 140 is not limited. That is to say, the die frame fixing platform 144 can be a vacuum holding stage, an electrostatic holding stage or a mechanical holding stage.

In some embodiments, the die frame fixing platform 144 can be driven by a driving device 146 (as shown in FIG. 2A), and the driving device 146 is used to control the movement of the die frame fixing platform 144, including horizontal movement, vertical movement, rotation and/or tilt and the like. The driving device 146 may include, for example, a robot arm, a motor, a gear, a linear transmission module 133 or a combination thereof.

In some embodiments, the pick-and-placer 110 is arranged on the transfer platform 130, the transfer platform 130 can be driven by a driver 132, and the driver 132 is used to control the movement of the transfer platform 130, including horizontal movement, vertical movement, rotation and/or tilting etc. The driver 132 is, for example, a robot arm, a motor, a gear, a linear transmission module 133 or a combination thereof. The driver 132 is used to control the pick-and-placer 110 to move to a location under the carrier 10, so that the pick-and-placer 110 bonds the die 20 to the bearing surface 11 of the carrier 10 from the location under the carrier 10.

In some embodiments, the die frame 140 and the carrier 10 are disposed to face downward, therefore, the driver 132 does not need to control the transfer platform 130 to rotate 180 degrees, but keeps the die 20 facing upwards and the transfer platform 130 moving horizontally between the die frame 140 and the carrier 10.

As shown in FIGS. 2A and 2B, the driver 132 controls the pick-and-placer 110 to move to a location under the die frame 140, and the suction head 112 of the pick-and-placer 110 moves upward to pick up a die 20, and the die 20 is placed on the dicing tape142. Therefore, although the die 20 is set downward, the die 20 adheres to the dicing tape 142 without falling. Next, the driver 132 controls the pick-and-placer 110 to translate, so that the suction head 112 of the pick-and-placer 110 moves to a location under the carrier fixing platform 120, and the die 20 faces the carrier 10 located under the carrier fixing platform 120, and the bearing surface 11 of the carrier 10 is arranged to face downward. Then, the suction head 112 of the pick-and-placer 110 moves upward, so that the die 20 is bonded to the bearing surface 11 of the carrier 10.

In some embodiments, when the die frame 140 and the carrier 10 face downward, the particles 12 originally attached to the die frame 140 and the carrier 10 naturally fall down due to gravity. The particles 12 may easily be removed by other external forces (such as jet stream or electrostatic force). In addition, the combination of a metal-to-metal bonding and a dielectric-to-dielectric bonding or fusion bonding is used to bond the die 20 on the carrier 10, and the bonding film 16 can generate a weak Van der Waals force between the die 20 and the carrier 10, so that the die 20 will not drop from the carrier 10. Furthermore, the die 20 can be completely attached to the bonding film 16 without particles falling thereon, reducing the probability of forming voids due to incomplete bonding (non-bonding) between the die 20 and the carrier 10.

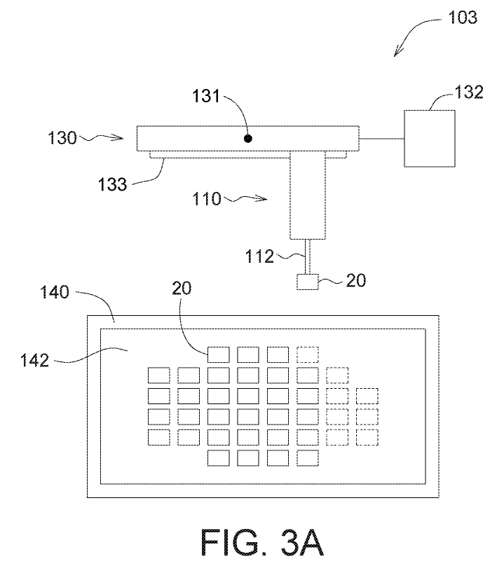

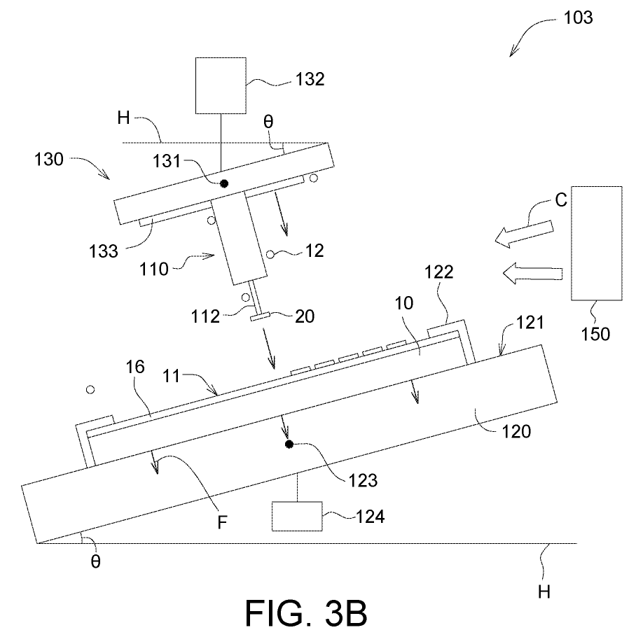

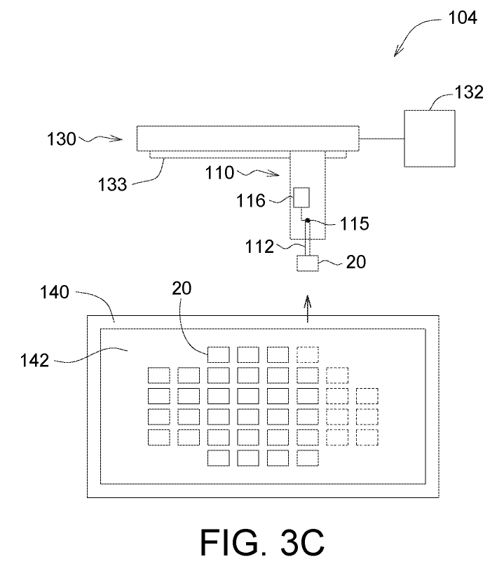

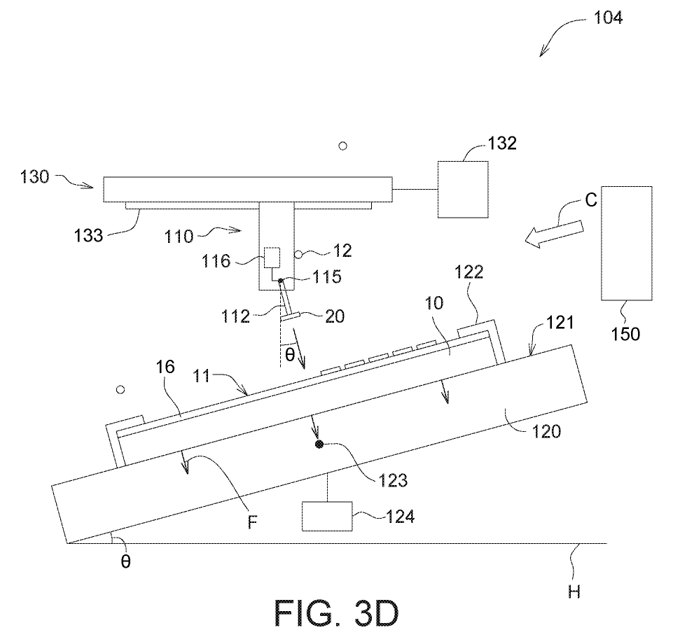

Referring to FIG. 3A and FIG. 3B, FIGS. 3A and 3B are schematic diagrams of a die bonding system 103 and a die bonding method according to another embodiment of the present disclosure. The die bonding system 103 includes a pick-and-placer 110, a die frame 140, a carrier fixing platform 120 and a transfer platform 130. The pick-and-placer 110 includes a suction head 112, the suction head 112 is used to pick up a die 20 and place the die 20 on a carrier 10, the carrier fixing platform 120 is used to fix the carrier 10, the carrier 10 has a bearing surface 11 which is inclined at an angle θ with respect to the horizontal plane H. The transfer platform 130 includes a driver 132, the pick-and-placer 110 is arranged on the transfer platform 130, the driver 132 controls the pick-and-placer 110 to tilt an angle θ relative to the horizontal plane H, and the pick-and-placer 110 bonds the die 20 to the bearing surface 11 of the carrier 10 at the angle θ of tilt. In an embodiment, the tilt angle θ is, for example, greater than 5 degrees and less than 90 degrees. In one embodiment, the tilt angle θ is, for example, between about 25 degrees and about 35 degrees, or is larger than 35 degrees or smaller than 25 degrees.

In some embodiments, the die frame 140 is arranged to face upward, and the carrier 10 is inclined at an angle θ relative to the horizontal plane H and faces a predetermined direction (non-vertical direction). Therefore, the driver 132 does not need to control the transfer platform 130 to rotate 180 degrees, but rotate a small range of angle θ. For example, the driver 132 controls the transfer platform 130 to rotate about 25 degrees to about 35 degrees. After the transfer platform 130 rotates a predetermined angle θ, it can keep moving horizontally between the die frame 140 and the carrier 10.

In some embodiments, after one or more semiconductor processes is done on the carrier fixing platform 120, it is inevitable that some particles 12 adhere to the surface of the carrier fixing platform 120. The particles 12 may come from the particles 12 in the gas, the pollutants generated during the process, the particles 12 originally attached to the carrier, or other devices that generate the particles 12. The particles 12 may contaminate the carrier 10 in the die bonding process to produce a defective carrier 10 (such as a wafer).

In FIG. 3B, in order to remove the particles 12 from the surface of the carrier fixing platform 120 or the particles 12 originally attached to the carrier 10 before the die bonding process, the carrier fixing platform 120 and the carrier 10 are arranged from an upward setting to an inclined setting, so that the bearing surface 121 of the carrier fixing platform 120 and the bearing surface 11 of the carrier 10 are obliquely disposed with respect to horizontal plane H. When the carrier fixing platform 120 and the carrier 10 are disposed to be inclined, an airflow C can be provided by a removing device 150 (for example, a jet stream or an air flow C) to pass through the carrier fixing platform 120, so that the particles 12 are taken away by the airflow C from the surface of the carrier 10. Therefore, when the carrier fixing platform 120 and the carrier 10 are disposed to be inclined, the bearing surface 11 of the carrier 10 can keep clean without being polluted by the particles 12 or other undesired contaminants.

In some embodiments, the carrier fixing platform 120 can use mechanical elements, vacuum adsorption elements, electrostatic adsorption elements, clamping elements or other elements to hold the carrier 10. As shown in FIG. 3B, at least two fixing parts 122 are provided on the bearing surface 11 of the carrier fixing platform 120, such as hooks or chucks, and the two fixing parts 122 hold the carrier 10 on the top of the carrier fixing platform 120. Alternatively, the carrier 10 can be adsorbed onto the carrier fixing platform 120 by electrostatic force or vacuum suction (the arrows on the rear of the substrate 10 shown in FIG. 3B face downward to indicate the suction force F). Therefore, the use of mechanical elements or clamping elements to hold the carrier 10 is not limited. That is to say, the carrier fixing platform 120 can be a vacuum holding stage, an electrostatic holding stage or a mechanical holding stage.

In some embodiments, the carrier fixing platform 120 can be driven by a driving device 124, and the driving device 124 is used to control the movement of the carrier fixing platform 120, including horizontal movement, vertical movement, rotation and/or tilting, etc. The driving device 124 may include, for example, a robot arm, a motor, a gear, a linear transmission module or a combination thereof. As shown in FIG. 3B, the carrier fixing platform 120 includes a rotating shaft 123, and the driving device 124 can control the carrier fixing platform 120 to rotate relative to the rotating shaft 123 to tilt a predetermined angle θ. The tilt angle θ is, for example, greater than 5 degrees and less than 90 degrees. In one embodiment, the tilt angle θ is, for example, between about 25 degrees and about 35 degrees.

In some embodiments, the pick-and-placer 110 is arranged on the transfer platform 130, and the transfer platform 130 can be driven by a driver 132, and the driver 132 is used to control the movement of the transfer platform 130, including horizontal movement, vertical movement, rotation and/or tilt, etc. The driver 132 may include, for example, a robot arm, a motor, a gear, a linear transmission module 133 or a combination thereof. The driver 132 is used to control the transfer of the pick-and-placer 110 to the top of the carrier 10, so that the pick-and-placer 110 bonds the die 20 to the bearing surface 11 of the carrier 10 from the top of the carrier 10. As shown in FIG. 3A, the transfer platform 130 includes a rotation shaft 131, and the driver 132 controls the transfer platform 130 to rotate relative to the rotation shaft 131 to tilt at a predetermined angle θ. The tilt angle θ is, for example, greater than 5 degrees and less than 90 degrees. In one embodiment, the tilt angle θ is, for example, between about 25 degrees and about 35 degrees.

As shown in FIGS. 3A and 3B, the driver 132 controls the pick-and-placer 110 to move to a location on the top of the die frame 140, and the suction head 112 of the pick-and-placer 110 moves downward to pick up a die 20, and the die 20 is placed on the dicing tape 142. Next, the driver 132 controls the pick-and-placer 110 to rotate at an angle θ, so that the pick-and-placer 110 and the die 20 are tilted and translated. Next, the suction head 112 of the pick-and-placer 110 is moved to a location on the top of the carrier fixing platform 120, and the tilted die 20 faces the carrier 10 located on the top of the carrier fixing platform 120. Then, the suction head 112 of the pick-and-placer 110 moves toward the carrier 10, so that the die 20 is bonded to the bearing surface 11 of the carrier 10.

In some embodiments, when the carrier 10 and the carrier fixing platform 120 are disposed to be inclined, the particles 12 originally attached to the die frame 140 and the carrier 10 can be removed by a removing device 150 (such as a jet stream or an airflow C provided from the removing device 150), so that the die 10 can be completely attached to the bonding film without particles falling thereon, reducing the probability of forming voids due to incomplete bonding (non-bonding) between the die 10 and the carrier 20.

Referring to FIG. 3C and FIG. 3D, FIGS. 3C and 3D are schematic diagrams of a die bonding system 104 and a die bonding method using the same according to another embodiment of the present disclosure. The die bonding system 104 includes a pick-and-placer 110, a die frame 140, a carrier fixing platform 120 and a transfer platform 130. The related description of the die bonding system 104 in FIG. 3C and FIG. 3D is similar to the die bonding system 103 and thus will not be repeated here. In some embodiments, the pick-and-placer 110 is disposed on the transfer platform 130, and the transfer platform 130 includes a linear transmission module 133 (such as a slide rail), for example, and the pick-and-placer 110 can move through the linear transmission module 133, so that the pick-and-placer 110 can keep moving horizontally between the die frame 140 and the carrier 10. In addition, the suction head 112 of the pick-and-placer 110 includes a rotating shaft 115 and a driving device 116, and the driving device 116 is used to control the suction head 112 to rotate with respect to the rotating shaft 115 to tilt an angle θ, so that the suction head 112 and the die 20 are arranged to be inclined. The tilt angle θ is, for example, greater than 5 degrees and less than 90 degrees. In one embodiment, the tilt angle θ is, for example, between about 25 degrees and about 35 degrees.

As shown in FIG. 3C and FIG. 3D, when the pick-and-placer 110 moves to the top of the die frame 140, the suction head 112 of the pick-and-placer 110 moves downward to pick up a die 20. Then, the driver 132 controls the pick-and-placer 110 to move through the linear transmission module 133, so that the suction head 112 of the pick-and-placer 110 is transferred to the top of the carrier fixing platform 120. Next, the driving device 116 controls the suction head 112 to rotate relative to the rotating shaft 115 to tilt an angle θ, and the suction head 112 and the die 20 are arranged to be inclined. Next, the suction head 112 of the pick-and-placer 110 moves toward the carrier 10, so that the die 20 is bonded to the bearing surface 11 of the carrier 10 at the angle θ of tilt. After the bonding step of the die 20 is completed, the driving device 116 controls the suction head 112 to reversely rotate relative to the rotation shaft 115 to be set downward (as shown in FIG. 3C), so as to pick up another die 20 and repeat the above-mentioned bonding step for the another die 20.

Referring to FIG. 4A and FIG. 4B, FIGS. 4A and 4B are schematic diagrams of a die bonding system 105 and a die bonding method according to another embodiment of the present disclosure. The die bonding system 105 includes a pick-and-placer 110, a die frame 140, a die frame fixing platform 144, a carrier fixing platform 120 and a transfer platform 130. The pick-and-placer 110 includes a suction head 112 for picking up a die 20 and placing the die 20 on a carrier 10. The die frame 140 is disposed on the bottom of the die frame fixing platform 144, and the die frame 140 is disposed to be inclined. The carrier fixing platform 120 is used to fix the carrier 10, the carrier 10 has a bearing surface 11, and the bearing surface 11 is disposed to face downward. The transfer platform 130 includes a driver 132, the pick-and-placer 110 is arranged on the transfer platform 130, the driver 132 controls the pick-and-placer 110 to tilt an angle θ with respect to the horizontal plane H, and controls the pick-and-placer 110 to move to a location under the carrier 10, and the pick-and-placer 110 bonds the wafer 20 to the bearing surface 11 of the carrier 10.

In some embodiments, the die frame 140 is disposed to be inclined, and the carrier 10 can be disposed to face downward or to be inclined. In some embodiments, the die frame fixing platform 144 can be driven by a driving device 146, and the driving device 146 is used to control the movement of the die frame fixing platform 144, including horizontal movement, vertical movement, rotation and/or tilting, etc. The driving device 146 may include, for example, a robot arm, a motor, a gear, a linear transmission module or a combination thereof.

In some embodiments, the die frame fixing platform 144 may utilize mechanical elements, vacuum adsorption elements, electrostatic adsorption elements, clamping elements or other elements to hold the die frame 140. As shown in FIG. 4A, at least two fixing parts 145, such as hooks or chucks, are disposed on the die frame fixing platform 144, and the two fixing parts 145 hold the die frame 140 on the bottom of the die frame fixing platform 144. Alternatively, the die frame 140 can be attached or fixed on the bottom of the die frame fixing platform 144 by electrostatic force or vacuum suction (the upward arrows shown in FIG. 4A on the rear of the die frame 140 indicates suction force F). Therefore, it is not limited to use mechanical elements or clamping elements to hold the die frame 140. That is to say, the die frame fixing platform 144 can be a vacuum holding stage, an electrostatic holding stage or a mechanical holding stage.

As shown in FIG. 4A, the driver 132 does not need to control the transfer platform 130 to rotate 180 degrees, but to rotate a small range of angles θ, for example, the driver 132 controls the transfer platform 130 to rotate about 25 degrees to about 35 degrees. After the transfer platform 130 rotates a predetermined angle θ, it can keep moving horizontally between the die frame 140 and the carrier 10, or the transfer platform 130 can be reversely rotated until the pick-and-placer 110 and the die 20 face upward, and then the driver 132 drives the pick-and-placer 110 to move horizontally between the die frame 140 and the carrier 10.

In FIG. 4B, in order to remove the particles 12 from the surface of the carrier fixing platform 120 and/or the particles 12 originally attached to the carrier 10 before the die bonding process, the carrier fixing platform 120 and the carrier 10 are set downward instead of upward, so that the bearing surface 121 of the carrier fixing platform 120 and the bearing surface 11 of the carrier 10 are set downward. Next, the driver 132 controls the pick-and-placer 110 to move laterally, so that the suction head 112 of the pick-and-placer 110 moves to a location under the carrier fixing platform 120, and the die 20 faces the carrier 10 located on the bottom of the carrier fixing platform 120, and the bearing surface 11 of the carrier 10 is set downward. Then, the suction head 112 of the pick-and-placer 110 moves upwards, so that the die 20 is bonded to the bearing surface 11 of the carrier 10.

The present disclosure relates to a die bonding system and a die bonding method using the same are provided for a pick-and-placer to pick up a die and place the die on the carrier, the carrier is arranged to face downward or inclined at an angle relative to the horizontal plane so as to avoid the contaminants falling on the carrier or the dies and eliminate the non-bonding interface between the carrier and the dies.

According to some embodiments of the present disclosure, a die bonding system is provided, including a pick-and-placer, a carrier fixing platform, and a transfer platform. The pick-and-placer is used to pick up a die and place the die on a carrier. The carrier fixing platform is used to fix the carrier. The carrier has a bearing surface facing downward. The transfer platform for controlling the pick-and-placer to move to a location under the carrier, and the pick-and-placer bonds the die to the bearing surface.

According to some embodiments of the present disclosure, a die bonding system is provided, including a pick-and-placer, a carrier fixing platform, and a transfer platform. The pick-and-placer for picking up a die and placing the die on a carrier. The carrier fixing platform is used to fix the carrier. The carrier has a bearing surface tilted for an angle relative to a horizontal plane. The transfer platform for controlling the pick-and-placer to bond the die to the bearing surface.

According to some embodiments of the present disclosure, a die bonding method is provided, including the following steps. A die is picked up through a pick-and-placer. the die is bonded to a bearing surface of a substrate through the pick-and placer. The substrate is fixed on a platform and the bearing surface is facing downward or inclined at an angle relative to a horizontal plane.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A die bonding system comprising:
a pick-and-placer comprising a suction head for picking up a die and placing the die on a carrier;
a carrier fixing platform for fixing the carrier, the carrier having a bearing surface facing downward and tilting an angle relative to a horizontal plane; and
a transfer platform for controlling the pick-and-placer to move to a location under the carrier, and the pick-and-placer bonds the die to the bearing surface.

2. The die bonding system according to claim 1, wherein the carrier is held under the carrier fixing platform by a suction force.

3. The die bonding system according to claim 1, wherein the substrate comprises a bonding film for bonding the die to the bearing surface.

4. The die bonding system according to claim 1, wherein the transfer platform comprises a rotation shaft and a driver, and the driver is used to control the transfer platform to rotate relative to the rotation shaft upward or downward.

5. The die bonding system according to claim 4, wherein the transfer platform comprises a linear transmission module, the pick-and-placer moves to the carrier fixing platform through the linear transmission module, and the driver is used to control a rotation of the linear transmission module relative to the rotating shaft.

6. The die bonding system according to claim 1, wherein the carrier fixing platform comprises at least one fixing part, and the at least one fixing part holds the carrier on a bottom of the carrier fixing platform.

7. The die bonding system according to claim 1, further comprising a die frame and a die frame fixing platform, the die frame is arranged under the die frame fixing platform, and the die is arranged on the die frame and faces downward.

8. The die bonding system according to claim 7, wherein the die frame fixing platform is driven by a driving device, and the driving device is used to control the die frame fixing platform to tilt at an angle relative to a horizontal plane.

9. The die bonding system according to claim 7, wherein the die frame fixing platform comprises a vacuum holding stage, an electrostatic holding stage or a mechanical holding stage.

10. A die bonding system comprising:
a pick-and-placer for picking up a die and placing the die on a carrier;
a carrier fixing platform for fixing the carrier, the carrier having a bearing surface tilted an angle relative to a horizontal plane; and
a transfer platform for controlling the pick-and-placer to bond the die to the bearing surface of the carrier at the angle of tilt.

11. The die bonding system according to claim 10, wherein the carrier fixing platform is driven by a driving device, the carrier fixing platform comprises a rotating shaft, and the driving device is used to control a rotation of the carrier fixing platform relative to the rotating shaft to tilt the angle.

12. The die bonding system according to claim 10, wherein the pick-and-placer is driven by a driver, the driver controls the pick-and-placer to rotate at the angle to tilt the pick-and-placer and the die, and the driver controls the pick-and-placer to move to a top of the carrier fixing platform.

13. The die bonding system according to claim 10, wherein the pick-and-placer comprises a suction head, a driving device and a rotating shaft, the driving device is used to control a rotation of the suction head relative to the rotating shaft to tilt the angle.

14. The die bonding system according to claim 10, further comprising a removing device for providing an airflow through the carrier fixing platform for removing particles on the carrier.

15. A die bonding system, comprising:
a carrier fixing platform configured to support a carrier, the carrier having a bearing surface;
a die frame fixing platform configured to support a die frame carrying a plurality of dies;
a pick-and-placer configured to pick up one of the dies from the die frame and place the die onto the bearing surface of the carrier;
a first driving mechanism coupled to the carrier fixing platform and configured to adjust an inclination angle of the carrier fixing platform relative to a horizontal plane; and
a second driving mechanism coupled to the pick-and-placer and configured to adjust an inclination angle of the pick-and-placer relative to the horizontal plane.

16. The die bonding system according to claim 15, wherein the second driving mechanism comprises a rotation shaft and a motor configured to rotate pick-and-placer upward or downward.

17. The die bonding system according to claim 15, wherein the inclination angle of the carrier fixing platform is equal to the inclination angle of the pick-and-placer.

18. The die bonding system according to claim 15, wherein the pick-and-placer moves between the die frame fixing platform and the carrier fixing platform along a linear transmission module.

19. The die bonding system according to claim 15, wherein the carrier comprises a bonding film disposed on the bearing surface for bonding the die thereto.

20. The die bonding system according to claim 15, further comprising a removing device for providing an airflow through the carrier fixing platform for removing particles on the carrier.
